(19) United States
(12) Patent Application Publication
(10) Pub. No.: US 2011/0116242 A1
(43) Pub. Date: May 19, 2011

(54) TAMPER EVIDENT PCBA FILM

(75) Inventors: Michael Richard Fabry, Apple Valley, MN (US); Robert Michael Echols, Jordan, MN (US); William Brad Green, Shakopee, MN (US)

(73) Assignee: Seagate Technology LLC, Scotts Valley, CA (US)

(21) Appl. No.: 12/621,260

(22) Filed: Nov. 18, 2009

(51) Int. Cl. H05K 1/18

(52) U.S. Cl. 361/748

(57) ABSTRACT

Method and apparatus for constructing and operating a printed circuit board assembly (PCBA). In some embodiments, a plurality of electronic components are attached to a first side of a substrate that has at least one electrical lead that connects the electrical components is present on an opposite second side of the substrate. A primary film is adhered to the second side of the substrate to create an air tight seal around each electrical lead. A secondary film is then adhered to the primary film and provides a cantilevered lift tab that extends outside the bounds of the primary film. The secondary film has a lower bond strength than the primary film.

### BACKGROUND

Electronic devices generally operate to store and retrieve data in a fast and efficient manner. Some storage devices utilize numerous chips on a circuit board to facilitate the various functions of the device.

As will be appreciated, the circuit board and corresponding chips can be subject to functional failure due to electrical shorting from corrosion and physical abuse. Moreover, the circuit board can be susceptible to tampering and unwanted alteration of chip functions. Such tampering can be especially hazardous when highly secure data is stored or accessed by the circuit board.

Historically, physical and environmental protection has been provided for circuit boards that fail to be compatible with practical thermal convection, high volume assembly processing, and reworking operations. The reliability of the circuit board may accordingly be hindered when physical and environmental damage occurs. Thus, physical and environmental protection means can have associated functionality issues that affect the circuit board so that considerable loss in efficiency and reliability is noticeable.

In these and other types of electronic devices, it is often desirable to increase physical and environmental protection as well as tamper evidence while providing efficient operation of a circuit board.

### SUMMARY

Various embodiments of the present invention are generally directed to a method and apparatus for protecting a printed circuit board assembly (PCBA) from functional failure due to electrical shorting from corrosion or physical abuse as well as showing tamper evidence

In accordance with various embodiments, a plurality of electronic components is attached to a first side of a substrate that has at least one electrical lead that connects electronic components on an opposite second side of the substrate. A primary film is adhered to the second side of the substrate to provide environmental and physical protection on the substrate and electrical leads by creating an air tight seal around each electrical lead. A secondary film is then adhered to the primary film and provides a cantilevered lift tab that extends outside the bounds of the primary film. The secondary film has lower bond strength than the primary film.

In other embodiments, a plurality of electronic components is provided and attached to a first side of a substrate that has at least one lead that connects the electrical components is present on an opposite second side of the substrate. A primary film is adhered to the second side of the substrate to create an air tight seal around each lead. A secondary film is then adhered to the primary film and provides a cantilevered lift tab that extends outside the bounds of the primary film. The secondary film has a lower bond strength than the primary film.

These and various other features and advantages which characterize the various embodiments of the present invention can be understood in view of the following detailed discussion and the accompanying drawings.

### BRIEF DESCRIPTION OF THE DRAWINGS

FIG. 1 is a generalized functional representation of an exemplary electronic device constructed and operated in accordance with various embodiments of the present invention.

FIG. 2 generally illustrates an exemplary printed circuit board.

FIGS. 3A and 3B show various views of the exemplary circuit board of FIG. 2 as constructed and operated in accordance with various embodiments of the present invention.

FIGS. 4A and 4B display various views of the exemplary circuit board of FIG. 2 as constructed and operated in accordance with various embodiments of the present invention.

FIG. 5 provides an exemplary tamper prevention and indication routine conducted in accordance with various embodiments of the present invention.

### DETAILED DESCRIPTION

The present disclosure relates to providing physical and environmental protection for a printed circuit board assembly (PCBA), and in particular to methods and structure that provides evidence of tampering with the PCBA. Current PCBA construction may protect against some physical and environmental damage, but are difficult to produce and exhibit inefficient productivity. As such, the integrity and reliability of a PCBA can be compromised by both voluntary and involuntary physical and environmental abuse.

In accordance with exemplary embodiments, the integrity of a PCBA can be improved by adhering a primary film to one side of the PCBA to create an air tight seal around each lead that connects the electrical components of the PCBA. A secondary film that has a lower bonding strength than the primary film can further be attached to the primary film and present a lift tab to facilitate removal of the secondary film without damage to the primary film.

As a result, the PCBA is protected from physical and environmental harm while indicating any attempted or successful tampering operations. Furthermore, the PCBA is protected while exhibiting efficient and reliable productivity. That is, the primary and secondary films can provide evidence of tampering while protecting the PCBA from environmental damage without hampering the PCBA's operation.

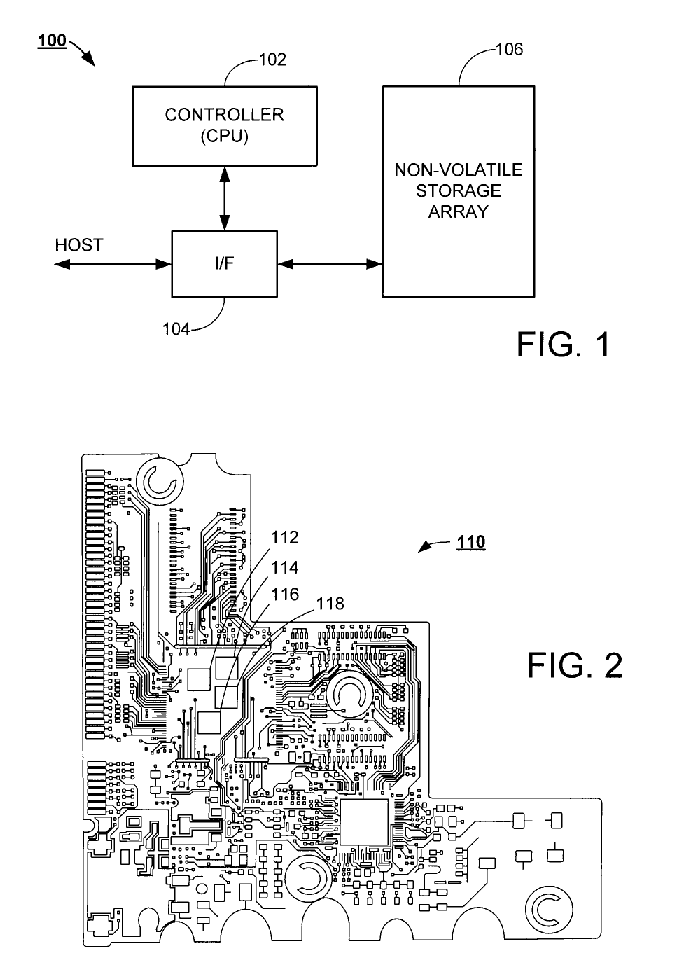

Turning to FIG. 1, a functional block representation of an exemplary data storage device 100 is provided. The device 100 includes a top level controller 102, an interface (I/F) circuit 104 and a non-volatile data storage array 106. The I/F circuit 104 operates under the direction of the controller 102 to transfer user data between the array 106 and a host device (not shown). In some embodiments, the controller 102 is a programmable microcontroller. Data can be buffered in the I/F circuit 104 pending a transfer of the data between the array 106 and the host device.

FIG. 2 displays an exemplary printed circuit board 110 capable of being used in the data storage device of FIG. 1. The functions of an electronic device 100 are controlled by the hardware installed on, and connected by, the printed circuit board 124. Hardware on a printed circuit board 124 can include an application specific integrated circuit (ASIC) controller 112, a memory buffer 114, a servo motor control logic 116, and a read channel signal processor 118.

It should be noted that the printed circuit board 110 can employ numerous individual chips with independent functions, individual chips with multiple functions, or a single package having multiple functions either alone or in combination with one another. For example the memory buffer 114 can consist of two dies: a non-volatile memory such as, but not limited to NOR flash, and a volatile memory such as, but not limited to dynamic RAM (DRAM).

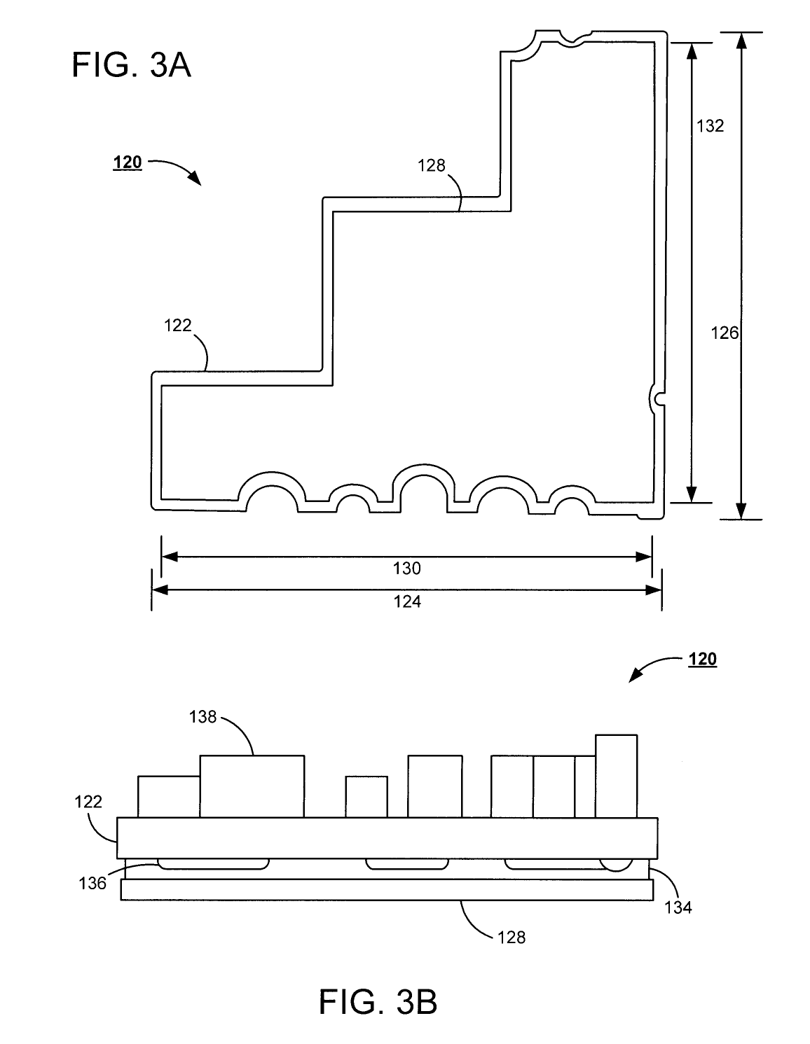

FIGS. 3A and 3B show various views of an exemplary PCBA 120 capable of being used in the data storage device of FIG. 1 and constructed in accordance with various embodiments of the present invention. The PCBA 120 has a substrate 122 that has an overall first length 124 and an overall first width 126. A primary film 128 is adhered to the substrate 122 and has an overall second length 130 and second width 132 that does not extend beyond the first width 124 and first length 126 of the substrate 122, as shown in FIG. 3A.

In FIG. 3B, the PCBA is displayed from a side view that illustrates the relationship between the substrate 122 and primary film 128 that includes an adhesive layer 134 that forms the air tight seal around each electrical lead 136. In various embodiments, the electrical leads 136 are constructed of copper material that is embedded into the substrate 122 as a trace. Further, the adhesive layer 134 is part of the primary film 128 and is affixed to the PCBA concurrently with the primary film 128. However, other embodiments of the present invention has the adhesive layer applied to the PCBA to enclose the electrical leads 136 and subsequently attaching the primary film to the adhesive layer 134.

It can be appreciated that the construction of the adhesive layer 134 is without limitation as the adhesive layer 134 can be cured to harden and form the air tight seal around each electrical lead 136 or a catalyst can be added to form such seals. In operation, the primary film 128 provides evidence of any tampering with the PCBA, including the electrical leads 136 as well as the corresponding electric components 138. In some embodiments, the primary film 128 is opaque so that no visual indication can be discerned about the configuration of the PCBA and electric components 138.

Furthermore, the seal around each electrical lead 136 provides environmental protection including corrosion resistance. As such, the adhesion of the primary seal 128 to the substrate 122 provides advantageous physical and chemical protection to the electrical components of the PCBA. With the implementation of the Federal Information Processing System Level 2 (FIPS 140-2), means of providing tamper-evident PCBA constructions have become particularly important in data storage devices. The use of the primary film 128 that adheres to and seals the electric components of the PCBA provides for protection against tampering while allowing thermal convection to cool the electric components 138 and substrate 122 and maintain a high productivity and reliability standard.

While the primary film 128 can be permanently affixed to the substrate 122, various embodiments of the present invention include the removal of the primary film 128 and adhesive layer 134 so that reworking and repair operations can be performed on the substrate 122, electrical leads 136, and electric components 138. It should be noted that the orientation of the various components of the PCBA 120 are merely exemplary and do not limit the possible configurations of the PCBA 120. For example, the adhesive layer 134 can be omitted while the primary film 128 creates an air tight seal around each electrical lead 136.

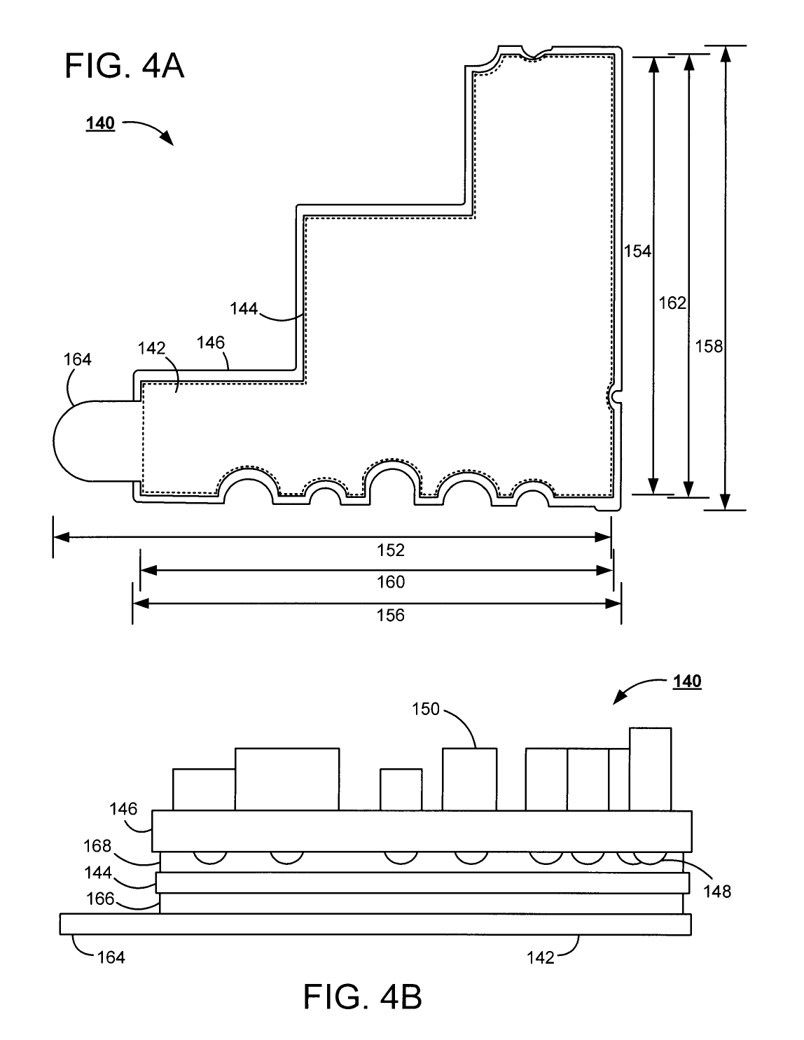

FIGS. 4A and 4B generally illustrate another exemplary PCBA 140 that is capable of being used in the data storage device of FIG. 1 and constructed in accordance with various embodiments of the present invention. During various times in the operational life of a PCBA, the PCBA 140 can be inadvertently deformed. One such time is during manufacturing of the PCBA 140 and/or a data storage device that implements the PCBA 140. In these and other times, a secondary film 142 can be adhered onto the primary film 144 which is affixed to the substrate 146 to seal each of the electrical leads 148 with an air tight seal. The secondary film 142 can provide protection against inadvertent physical and environmental damage to the primary film 144 as well as the electrical leads 148 and electric components 150.

As shown in FIG. 4A, the secondary film 142 is configured, in some embodiments, to have an overall third length 152 and an overall third width 154 that remain within the bounds of the respective first and second overall lengths 156, 158 and widths 160, 162 corresponding to the substrate 146 and primary film 144 except for a cantilevered lift tab 164. The cantilevered lift tab 164 can be positioned at any portion of the secondary film 142 and be configured in any number of sizes and shapes without deterring from the spirit of the present invention. The cantilevered lift tab 164 can allow for manual or automatic removal of the secondary film 142 without damage or disturbance of the underlying primary film 144.

FIG. 4B illustrates the PCBA 140 from a side view and shows the secondary film 142 is connected to the primary film 144 via a first adhesive layer 166. In some embodiments, the first adhesive layer 166 and associated secondary film 142 have a lower bonding strength than the second adhesive layer 168 corresponding to the primary film 144. It can be appreciated that the difference in bonding strength between the first and second adhesive layers 166 and 168 can be created by a variety of means including, but not limited to different adhesion materials, layer thicknesses, and curing times.

In some embodiments, the cantilevered lift tab 164 is formed at a corner of the secondary film 142 by rotary-die cutters and applied to the primary film 144 after the primary film 144 has been affixed to the substrate 146 and the second adhesive layer 168 has been cured. While the cantilevered lift tab 164 can permanently remain affixed to the primary film 144 during the operational life of the PCBA 140, the lift tab 164 can be engaged at any time to remove the secondary film 142 and associated first adhesive layer 166 without altering the primary film 144.

With a plurality of films protecting the electrical leads 148 and electric components 150, physical and environmental hazards can be significantly mitigated and eliminated. For example, the primary film 144 can be constructed of a polyvinyl chloride that is protected from heat and physical deformation during manufacturing by the secondary film 142. As the PCBA 140 is implemented into a data storage device, such as the data storage device of FIG. 1, the cantilevered lift tab 164 is engaged and removed to reveal a pristine primary film 144.

It should be noted that the removal of the secondary film 142 is expected to include the removal of the first adhesive layer 166. However, the first adhesive layer 166 can be removed subsequently to the secondary film 142 with a variety of techniques such as a solvent, as desired. As a result of using the secondary film 142, the primary film 144 is faultless and can provide reliable tamper-evident operation throughout the operational life of the PCBA 140.

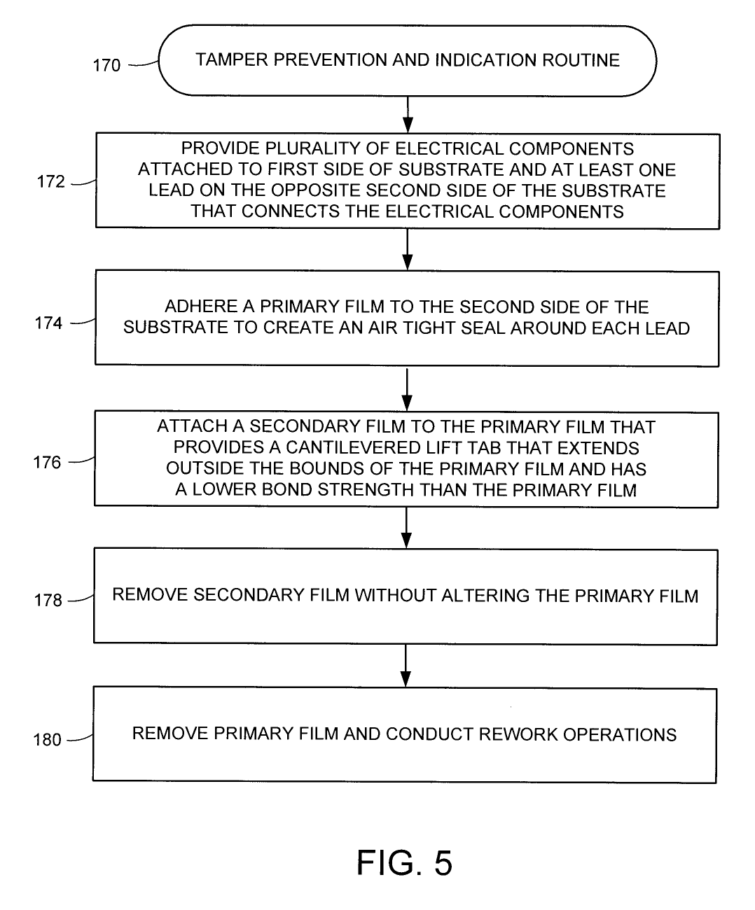

FIG. 5 displays a flow diagram of a tamper prevention and indication routine 170 performed in accordance with the various embodiments of the present invention. Initially in step 172, the routine 170 begins by providing a PCBA that has a plurality of electrical components that are attached to a first side of a substrate and electrically connected by electrical leads on the opposite second side of the substrate. It should be noted that the number and configuration of the various electrical components and electrical leads are not limited and can take any desired form. Step 174 adheres a primary film to the second side of the substrate to create an air tight seal around each electrical lead.

In various embodiments, the primary film does not exceed the bounds of the substrate, but in other embodiments the primary film extends beyond the bounds and attaches to at least one sidewall of the substrate. A secondary film is then attached to the primary film in step 176 and provides a cantilevered lift tab that extends outside the bounds of the primary film and has a lower bond strength than the primary film. While the routine 170 can end after step 176, the secondary film can optionally be removed from the primary film in step 178 to reveal a pristine primary film.

Finally in step 180, the primary film can be removed from the substrate so that rework operations can be conducted. Such rework operations are not required or limited and can include repairing and replacing various aspects of the PCBA, individually or in combination with the electrical leads and substrate of the PCBA. It should be noted that the term “rework” can include various operations in which aspects of the PCBA are modified and the PCBA is returned to operation with at least one portion of the PCBA unmodified. For example, a PCBA may be in operation with the primary film providing environmental protection and tamper evidence when an electrical component of the PCBA malfunctions and requires repair to which the primary film is removed, the electrical component is reworked, and a supplemental film is adhered to the PCBA to provide environmental and tamper protection. In such a exemplary operation, the PCBA would result in having at least one reworked electrical component and at least one original component that has not been modified or replaced during reworking.

Furthermore, the various steps of routine 170 are not required or limited and can be moved, deleted, or changed without deterring from the spirit of the present invention. For example, the primary film can be adhered to the substrate in step 174 without conducting any further steps. In yet another example, another primary film can be applied to the substrate after rework operations have been conducted in step 180.

As can be appreciated by one skilled in the art, the various embodiments illustrated herein provide advantages in both electronic device efficiency and reliability. The use of a plurality of protective films provides physical and chemical resistance while indicating any attempt or successful tampering operations. Moreover, the inclusion of the plurality of films does not hamper the efficient manufacture and operation of the PCBA. However, it will be appreciated that the various embodiments discussed herein have numerous potential applications and are not limited to a certain field of electronic media or type of data storage devices.

It is to be understood that even though numerous characteristics and advantages of various embodiments of the present invention have been set forth in the foregoing description, together with details of the structure and function of various embodiments of the invention, this detailed description is illustrative only, and changes may be made in detail, especially in matters of structure and arrangements of parts within the principles of the present invention to the full extent indicated by the broad general meaning of the terms in which the appended claims are expressed.

What is claimed is:

1. A printed circuit board assembly (PCBA) comprising:
a plurality of electronic components attached to a first side of a substrate, wherein at least one electrical lead that connects the electronic components is present on an opposite second side of the substrate;
a primary film adhered to the second side of the substrate to create an air tight seal around each electrical lead; and
a secondary film adhered to the primary film that provides a cantilevered lift tab that extends outside the bounds of the primary film, wherein the secondary film has a lower bond strength than the primary film.

2. The PCBA of claim 1, wherein the substrate has an overall first length and first width the primary film an overall second length and second width and the secondary film has an overall third length and third width, further wherein the overall first length and first width exceed the bounds of the overall second length and second width while being exceeded by the bounds of the overall third length and third width, and wherein the lift tab of the secondary film can be engaged to remove the secondary film from the substrate without disturbing the primary film.

3. The PCBA of claim 1, wherein the electrical lead is a copper trace that connects at least two electronic components.

4. The PCBA of claim 1, wherein the secondary film is removed after the substrate is installed in a computer system.

5. The PCBA of claim 1, wherein the secondary film is automatically removed during manufacturing.

6. The PCBA of claim 1, wherein the primary and secondary films are adhered to only one side of the substrate.

7. The PCBA of claim 1, wherein the primary film is an opaque tamper-evident film that permanently deforms upon physical engagement.

8. The PCBA of claim 1, wherein the air tight seal around the at least one lead provides physical and chemical protection for the at least one lead.

9. The PCBA of claim 1, wherein the secondary film prevents plastic deformation of the primary film during manufacturing.

10. The PCBA of claim 1, wherein a plurality of cantilevered lift tabs are provided by the secondary film that each extend beyond the bounds of both the primary film and the substrate.

11. A method comprising:
providing a plurality of electronic components attached to a first side of a substrate, wherein at least one electrical lead that connects the electronic components is present on an opposite second side of the substrate;
adhering a primary film to the second side of the substrate to create an air tight seal around each electrical lead; and
attaching a secondary film to the primary film that provides a cantilevered lift tab that extends outside the bounds of the primary film, wherein the secondary film has a lower bond strength than the primary film.

12. The method of claim 11, wherein the substrate has an overall first length and first width the primary film an overall second length and second width and the secondary film has an overall third length and third width, further wherein the overall first length and first width exceed the bounds of the overall second length and second width while being exceeded by the bounds of the overall third length and third width, and wherein the lift tab of the secondary film is engaged to remove the secondary film from the substrate without disturbing the primary film.

13. The method of claim 11, wherein the lift tab of the secondary film is manually engaged to remove the secondary film during manufacturing.

14. The method of claim 11, wherein the air tight seal around each lead is created by an adhesive layer that adheres the primary film to the substrate.

15. The method of claim 11, wherein the primary film is opaque and tamper-evident so that physical engagement permanently deforms the primary film.

16. The method of claim 11, wherein the secondary film is attached to a plurality of sidewalls of the substrate.

17. The method of claim 11, wherein removal of the primary film does not damage the substrate or electrical lead.

18. The method of claim 11, further comprising the step of removing the primary and secondary films to rework the at least one lead.

19. The method of claim 11, wherein the cantilevered lift tab is positioned at a corner of the secondary film.

20. An apparatus comprising:
a printed circuit board assembly (PCBA) with a plurality of electronic components each having at least one electrical lead that extends from a first side of a substrate to an opposite second side of the substrate to electrically connect the electronic components;
a film adhered to the second side of the substrate to create an air tight seal around each electrical lead which permanently deforms in response to physical engagement to identify tampering with the PCBA, and which can be removed to allow reworking of the PCBA for subsequent operation with at least one original and one reworked electrical component.
